(19) United States
(12) Patent Application Publication
(10) Pub. No.: US 2003/0127050 A1
(43) Pub. Date: Jul. 10, 2003

(54) Chemical vapor deposition apparatus

(75) Inventor: Keiichiro Kashihara, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/195,365

(22) Filed: Jul. 16, 2002

(30) Foreign Application Priority Data
Jan. 8, 2002 (JP) 2002-001537

(51) Int. Cl. C23C 16/00

(52) U.S. Cl. 118/715

(57) ABSTRACT

A CVD (chemical vapor deposition) apparatus is provided which deposits a film having uniform thickness and quality on a substrate. The CVD apparatus includes a partition wall for dividing a reactor chamber into a first space in which the substrate is to be placed and a second space into which a source gas is initially introduced, the second space being used as a gas storage chamber. The partition wall has a multiplicity of holes formed therein for uniformly supplying the source gas onto the substrate in the first space.

### BACKGROUND OF THE INVENTION

1. Field of the Invention

The present invention relates to a chemical vapor deposition apparatus (referred to hereinafter as a CVD apparatus) and, more particularly, to a CVD apparatus capable of depositing a uniform film on a substrate serving as a sample.

2. Description of the Background Art

FIG. 8 is a schematic view of a background art MOCVD (metal-organic CVD) apparatus. The background art MOCVD apparatus includes a reactor chamber body 101, and a reactor chamber cover (also known as a quartz bell jar or a quartz dome) 101b made of quartz and placed on the reactor chamber body 101 for sealing the reactor chamber body 101 to define a reactor chamber 102. A vertically movable support 103 is provided on a bottom portion 101a in the reactor chamber 102, and a substrate heater 105 for placing a substrate or wafer 104 thereon and for heating the substrate 104 is provided on the support 103. A source gas injector 107 for supplying an organic metal material gas 106 (referred to hereinafter as a source gas 106) into the reactor chamber 102 from the outside extends from the bottom portion 101a toward the reactor chamber cover 101b. The bottom portion 101a is also formed with an exhaust hole 108 positioned where the source gas injector 107 is not formed for reducing the pressure in the reactor chamber 102 and for exhausting the unreacted source gas 106, by-products and the like from the reactor chamber 102. An external heater 109 is provided for applying heat to the interior of the reactor chamber 102 through the cover 101b from outside the reactor chamber 102.

In the MOCVD apparatus having the above construction, the source gas 106 supplied from the source gas injector 107 is thermally decomposed on the surface of the substrate 104 and in the interior of the reactor chamber 102 both heated by the external heater 109 and the substrate heater 105, and a resultant decomposition product and a chemical reaction form a thin film on the substrate 104.

The external heater (or heat supply element) 109 have the function of suppressing the adsorption of the source gas 106 onto wall surfaces of the reactor chamber body 101 and the like and the function of speeding up a pre-reaction of the source gas 106 in addition to the above-mentioned heating function. Additionally, the source gas injector 107 extending from the bottom portion 101a toward the reactor chamber cover 101b can supply the source gas 106 to an interior region of the reactor chamber 102 heated to the highest temperature by the external heater 109. This speeds up the pre-reaction of the source gas 106.

In the background art MOCVD apparatus, however, the source gas 106 introduced through the source gas injector 107 flows along a flow 110 shown in FIG. 8 to produce a film which is thinner on one side 104b of the substrate 104 than on the other side 104a thereof and which is higher in composition concentration on the one side 104b than on the other side 104a, resulting in nonuniform film quality. In particular, a gas supply rate-determining process is susceptible to the flow of the source gas 106 to cause the formation of a more nonuniform film.

### SUMMARY OF THE INVENTION

It is an object of the present invention to provide a CVD apparatus capable of forming a film having uniform thickness and quality on a substrate.

According to a first aspect of the present invention, the chemical vapor deposition apparatus for forming a film on a substrate includes a reactor chamber, a partition wall, a multiplicity of holes, and a gas feed passage.

The reactor chamber receives the substrate therein. The partition wall divides the reactor chamber into a first space in which the substrate is to be placed, and a second space in which the substrate is not to be placed. The multiplicity of holes are formed in the partition wall. The gas feed passage supplies a source gas into the second space.

The source gas is initially stored in the second space and is introduced through the multiplicity of holes formed in the partition wall into the first space. Thus, the source gas is supplied uniformly into the first space, whereby the film having uniform thickness and quality is formed on the substrate.

Preferably, in the chemical vapor deposition apparatus, the partition wall is formed to cover the substrate from above.

This allows more uniform supply of the source gas onto the substrate from above the substrate.

Preferably, the chemical vapor deposition apparatus further includes a heat supply element for applying heat to the second space. The partition wall is made of quartz.

The heat supply element suppresses the adsorption of the source gas onto wall surfaces of the reactor chamber and the like, and speeds up a pre-reaction of the source gas. The partition wall made of quartz is resistant to heat supplied from the heat supply element to minimize impurities removed from the partition wall due to the heat.

Preferably, in the chemical vapor deposition apparatus, the partition wall and a surface of the reactor chamber opposed thereto are of a curved configuration.

This causes the source gas to flow along the surface of the reactor chamber and the partition wall having the curved configuration, thereby distributing the source gas more uniformly throughout the second space.

Preferably, in the chemical vapor disposition apparatus, the multiplicity of holes include a pair of holes. The pair of holes are disposed symmetrically with respect to the substrate as viewed in plan and have respective axes extending in a different direction from a line passing through the pair of holes and the center of the substrate.

This produces a spiral flow of the source gas about the substrate to achieve more uniform supply of the source gas to the upper surface of the substrate while the substrate is fixed.

According to a second aspect of the present invention, the chemical vapor deposition apparatus for forming a film on a substrate includes a reactor chamber, and at least two gas feed passages.

The reactor chamber receives the substrate therein. The at least two gas feed passages are equidistantly spaced circumferentially about the substrate for supplying a source gas into the reactor chamber.

This supplies the source gas from the symmetrical locations with respect to the substrate to produce uniform flows of the source gas within the reactor chamber. This allows the deposition of the film having uniform thickness and quality on the substrate.

Preferably, the chemical vapor deposition apparatus further includes a vaporizer, and at least two valves.

The single vaporizer generates the source gas. The at least two valves are open alternatively, and are formed between the vaporizer and the at least two gas feed passages, respectively.

The source gas is introduced into the reactor chamber alternatively through the source gas feed passages. The use of only the single vaporizer for controlling the amount of the source gas to be supplied simplifies the apparatus and reduces costs. The at least two valves can precisely control the supply of the source gas into the reactor chamber.

Preferably, the chemical vapor deposition apparatus further includes an inert gas feed passage for introducing an inert gas into one of the at least two gas feed passages which is not supplying the source gas.

Feeding the inert gas into the source gas feed passage which is not supplying the source gas prevents a source of unwanted deposits such as agglomerates of the source gas and the like.

Preferably, the chemical vapor deposition apparatus further includes a partition wall, and a multiplicity of holes.

The partition wall divides the reactor chamber into a first space in which the substrate is to be placed, and a second space in which the substrate is not to be placed. The multiplicity of holes are formed in the partition wall.

The at least two gas feed passages supply the source gas into the second space.

The equidistantly spaced source gas feed passages supply the source gas uniformly throughout the second space. The source gas is supplied through the partition wall having the multiplicity of holes formed therein uniformly onto the substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing a construction of an MOCVD apparatus according to a first preferred embodiment of the present invention;

FIG. 2 is a schematic sectional view showing a positional relationship between holes in a partition wall as viewed from above according to a second preferred embodiment of the present invention;

FIG. 3 is a schematic view showing a construction of the MOCVD apparatus according to a third preferred embodiment of the present invention;

FIG. 4 is a schematic view showing a positional relationship between a plurality of source gas injectors as viewed from above;

FIG. 5 is a schematic view showing connection between the plurality of source gas injectors and a vaporizer;

FIG. 6 is a schematic view showing a construction of the MOCVD apparatus according to a fourth preferred embodiment of the present invention;

FIG. 7 is a schematic view showing a construction of the MOCVD apparatus according to a fifth preferred embodiment of the present invention; and

FIG. 8 is a schematic view showing a construction of a background art MOCVD apparatus.

### DESCRIPTION OF THE PREFERRED EMBODIMENTS

The present invention will now be described in detail with reference to the drawings illustrating preferred embodiments of the present invention. The same reference numerals and characters as in the background art are used to designate identical or similar parts.

<First Preferred Embodiment>

FIG. 1 is a schematic view of an MOCVD apparatus according to a first preferred embodiment of the present invention. The apparatus according to the first preferred embodiment includes a reactor chamber body 101, and a reactor chamber cover 101b made of quartz and placed on the reactor chamber body 101 for sealing the reactor chamber body 101 to define a reactor chamber 102. A vertically movable support 103 is provided on a bottom portion 101a in the reactor chamber 102, and a substrate heater 105 for placing a substrate or wafer 104 thereon and for heating the substrate 104 is provided on the support 103. A source gas injector (or gas feed passage) 107 for supplying a source gas 106 into the reactor chamber 102 from the outside extends from the bottom portion 101a toward the reactor chamber cover 101b. The bottom portion 101a is also formed with an exhaust hole 108 positioned where the source gas injector 107 is not formed for reducing the pressure in the reactor chamber 102 and for exhausting the unreacted source gas 106, by-products and the like from the reactor chamber 102. An external heater (or heat supply element) 109 is provided for applying heat to the interior of the reactor chamber 102 through the cover 101b from outside the reactor chamber 102 at a temperature of not less than 500° C.

In the reactor chamber 102 defined by the reactor chamber body 101 and the cover 101b, there is provided a partition wall 1 for dividing the reactor chamber 102 into a space 2 (or first space) in which the substrate 104 is to be placed and a space 3 (or second space) in which the substrate 104 is not to be placed. The partition wall 1 is formed to cover the substrate 104 from above, and has a multiplicity of holes 1a formed therein. The size, number and arrangement of the multiplicity of holes 1a are suitably selected in accordance with a film to be formed on the substrate 104. The source gas injector 107 passes through the first space 2 and has a feed port in the second space 3 so that the source gas 106 initially enters the second space 3.

With such an arrangement according to the first preferred embodiment, the source gas 106 initially fills the second space 3, and is then fed through the multiplicity of holes 1a into the first space 2. This provides the source gas 106 uniformly into the first space 2 through the multiplicity of holes 1a. Thus, the provision of the partition wall 1 having the multiplicity of holes 1a so as to cover the substrate 104 from above allows more uniform supply of the source gas 106 onto the substrate 104. The uniform supply of the source gas 106 achieves the deposition of a film having uniform thickness and quality.

Although the cover 101b and the partition wall 1 may be made of metal (aluminum, stainless steel or the like), the use of the cover 101b and the partition wall 1 both made of quartz which is highly heat resistant and contains a small amount of impurity ensures resistance to heat supplied from the external heater 109 to minimize the impurity removed from the cover 101b and the partition wall 1 due to the heat, thereby minimizing the influence of the impurity upon the substrate 104. Other heat-resistant materials having a high purity may be used instead as the material of the cover 101b and the partition wall 1.

The cover 101b (or a surface of the reactor chamber 102 opposed to the partition wall 1) and the partition wall 1 may be of any configuration. However, the use of the curved configuration causes the source gas 106 to flow along the curve, thereby distributing the source gas 106 more uniformly throughout the second space 3.

<Second Preferred Embodiment>

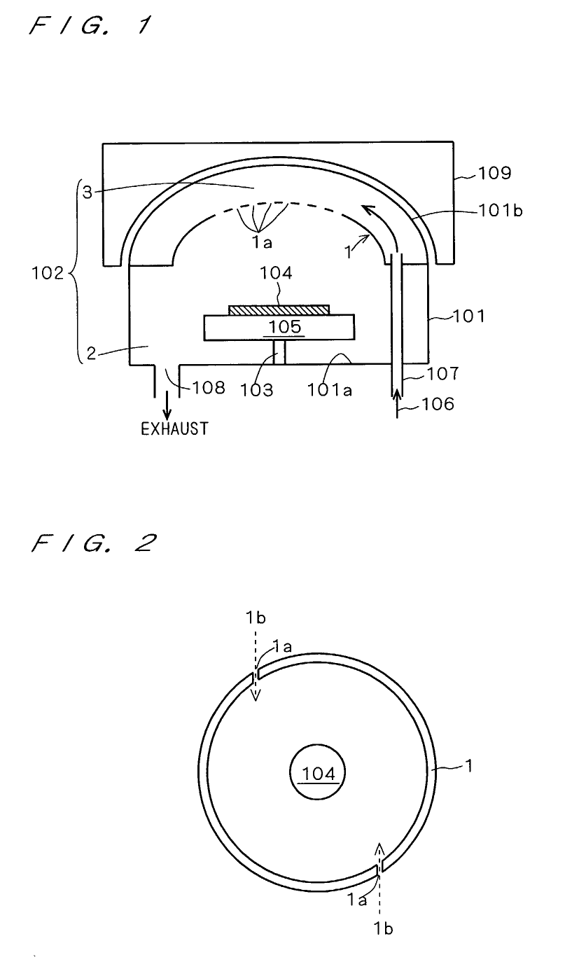

The multiplicity of holes 1a of the first preferred embodiment are arranged in a manner to be described below according to a second preferred embodiment of the present invention. FIG. 2 is a schematic sectional view taken along a plane passing through the partition wall 1 when the reactor chamber 102 is viewed from above (although a minimum number of holes 1a required to illustrate the feature of the second preferred embodiment are depicted in FIG. 2). As shown in FIG. 2, the holes 1a are positioned on the partition wall 1 symmetrically with respect to the substrate 104, and the symmetric holes 1a have respective axes 1b parallel to each other and directed toward other than the center of the substrate 104. The multiplicity of holes 1a having such an arrangement are formed in the partition wall 1.

The formation of the multiplicity of holes 1a in the above-mentioned positional relationship in the partition wall 1 produces a spiral gas flow about the substrate 104 to achieve more uniform supply of the source gas 106 to the upper surface of the substrate 104 while the substrate 104 is fixed. This further improves the uniformity in the surface of the film deposited on the substrate 104.

The holes 1a in each pair need not be disposed completely symmetrically with respect to the substrate, but may be slightly shifted from the symmetric positions so far as the above-mentioned effect is produced. The axes 1b of the holes 1a need not be completely parallel to each other so far as the holes 1a can produce the above-mentioned gas flow.

<Third Preferred Embodiment>

FIG. 3 is a schematic view of the MOCVD apparatus according to a third preferred embodiment of the present invention. The apparatus according to the third preferred embodiment includes the reactor chamber body 101, and the reactor chamber cover 101b made of quartz and placed on the reactor chamber body 101 for sealing the reactor chamber body 101 to define the reactor chamber 102. The vertically movable support 103 is provided on the bottom portion 101a in the reactor chamber 102. The substrate heater 105 for placing the substrate 104 thereon and for heating the substrate 104 is provided on the support 103. The external heater 109 is provided for applying heat to the interior of the reactor chamber 102 through the cover 101b from outside the reactor chamber 102 at a temperature of not less than 500° C. A plurality of source gas injectors (or gas feed passages) 107 for supplying the source gas 106 into the reactor chamber 102 from the outside extend from the bottom portion 101a toward the reactor chamber cover 101b.

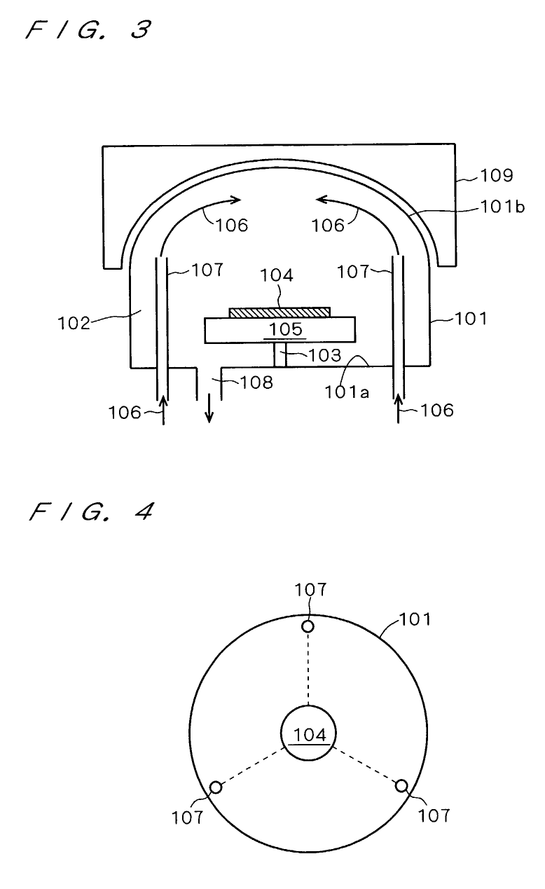

Although two source gas injectors 107 are shown in FIG. 3 as disposed symmetrically with respect to the substrate 104, two or more source gas injectors 107, if provided, are equidistantly spaced circumferentially about the substrate 104. For example, three source gas injectors 107 are spaced 120° from each other about the substrate 104, as shown in FIG. 4 (which is a schematic view of the reactor chamber body 101 as viewed from above).

The bottom portion 101a is also formed with the exhaust hole 108 positioned where the source gas injectors 107 are not formed for reducing the pressure in the reactor chamber 102 and for exhausting the unreacted source gas 106, by-products and the like from the reactor chamber 102.

In the background art MOCVD apparatus, the single source gas injector 107 produces a flow of the source gas 106 in one direction within the reactor chamber 102 to result in the nonuniform film deposited on the substrate 104. On the other hand, the provision of the plurality of source gas injectors 107, as in the above-mentioned construction, which supply the source gas 106 from the symmetrical locations with respect to the substrate 104 produces uniform flows of the source gas 106 within the reactor chamber 102. This allows the deposition of the film having uniform thickness and quality on the substrate 104.

A vaporizer may be connected to each of the source gas injectors 107 to simultaneously introduce the source gas 106 into the reactor chamber 102. Otherwise, as illustrated in FIG. 5, the source gas 106 generated by a single vaporizer 4 may be introduced through two valves 5 which are not simultaneously open (or which are open alternatively) into the individual source gas injectors 107, thereby to enter the reactor chamber 102 alternately through the source gas injectors 107. In either case, the film having uniform thickness and quality is deposited on the substrate 104. The latter technique uses only the single vaporizer 4 to control the amount of the source gas 106 to be supplied, thereby simplifying the apparatus and reducing costs. The use of valves which are open simultaneously makes it impossible to precisely control the amount of the source gas 106 to be supplied to all of the source gas injectors 107. However, the use of the valves which are not simultaneously open (or which are open alternatively) for supply of the source gas 106 alternately from the individual source gas injectors 107 allows the precise supply of the source gas 106 into the reactor chamber 102.

<Fourth Preferred Embodiment>

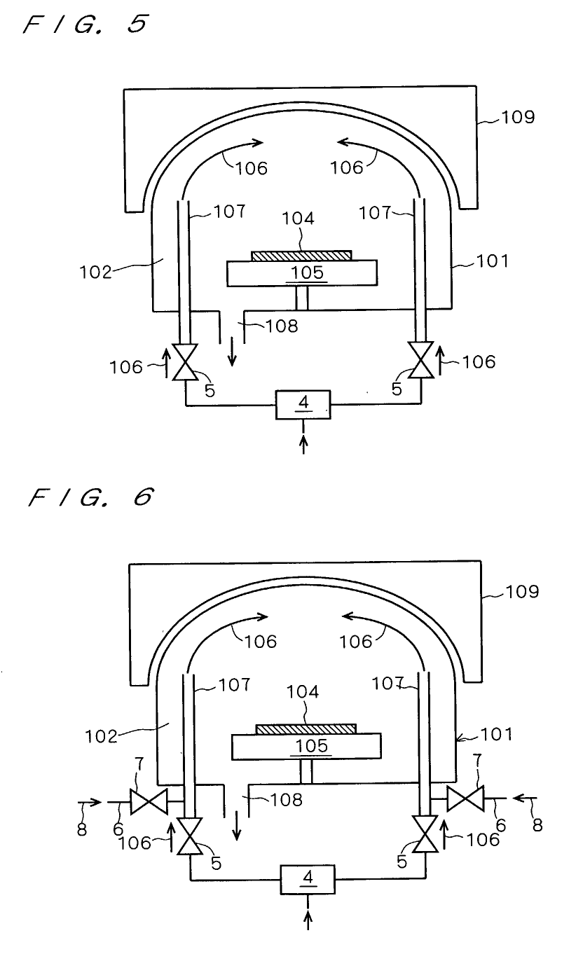

FIG. 6 shows the MOCVD apparatus according to a fourth preferred embodiment of the present invention. As shown in FIG. 6, the plurality of source gas injectors 107 described in the third preferred embodiment (from which the source gas 106 is alternatively supplied into the reactor chamber 102) are provided with feed ports (or inert gas feed passages) 6 connected through valves 7, respectively, in addition to the vaporizer 4.

In the apparatus according to the third preferred embodiment, deposits (or agglomerates resulting from the source gas 106) are deposited on one of the source gas injectors 107 which is not supplying the source gas 106. Thus, the source gas injector 107 which is not supplying the source gas 106 becomes a source of contamination or foreign matter for the substrate 104.

In the apparatus having the above-mentioned construction according to the fourth preferred embodiment, an inert gas 8 is fed into the source gas injector 107 which is not supplying the source gas 106 to prevent the source gas injector 107 from becoming a source of unwanted deposits. This consequently suppresses the generation of defect-causing contamination or foreign matter on the substrate 104.

<Fifth Preferred Embodiment>

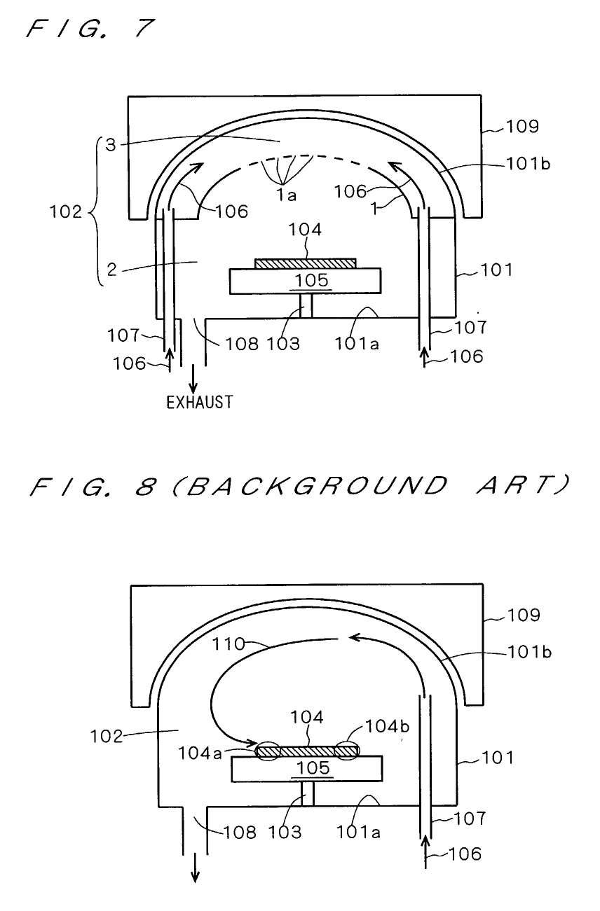

A fifth preferred embodiment according to the present invention is the combination of the first or second preferred embodiment and the third or fourth preferred embodiment. The MOCVD apparatus according to the fifth preferred embodiment is shown in FIG. 7.

The apparatus according to the fifth preferred embodiment includes the reactor chamber body 101, and the reactor chamber cover 101b made of quartz and placed on the reactor chamber body 101 for sealing the reactor chamber body 101 to define the reactor chamber 102. The vertically movable support 103 is provided on the bottom portion 101a in the reactor chamber 102. The substrate heater 105 for placing the substrate 104 thereon and for heating the substrate 104 is provided on the support 103. The external heater 109 is provided for applying heat to the interior of the reactor chamber 102 through the cover 101b from outside the reactor chamber body 101 at a temperature of not less than 500° C. The plurality of source gas injectors 107 for supplying the source gas 106 from the outside of the reactor chamber body 101 into the reactor chamber 102 extend from the bottom portion 101a toward the reactor chamber cover 101b. Although two source gas injectors 107 are shown in FIG. 7 as disposed symmetrically with respect to the substrate 104, two or more source gas injectors 107, if provided, are equidistantly spaced circumferentially about the substrate 104. The bottom portion 101a is also formed with the exhaust hole 108 positioned where the source gas injectors 107 are not formed for reducing the pressure in the reactor chamber 102 and for exhausting the unreacted source gas 106, by-products and the like from the reactor chamber 102. In the reactor chamber 102, the partition wall 1 is provided for dividing the reactor chamber 102 into the first space 2 in which the substrate 104 is to be placed and the second space 3 in which the substrate 104 is not to be placed. The partition wall 1 is formed to cover the substrate 104 from above, and has the multiplicity of holes 1a formed therein. The size, number and arrangement of the multiplicity of holes 1a are suitably selected in accordance with the film to be formed on the substrate 104. Each of the source gas injectors 107 passes through the first space 2 and has a feed port in the second space 3 so that the source gas 106 initially enters the second space 3.

The multiplicity of holes 1a are positioned on the partition wall 1 symmetrically with respect to the substrate 104, and the symmetric holes 1a may have respective axes substantially parallel to each other and directed toward other than the center of the substrate 104, as in the second preferred embodiment (see FIG. 2). The plurality of source gas injectors 107 (from which the source gas 106 is alternatively supplied into the reactor chamber 102) may be provided with the feed ports 6 connected through the valves 7, respectively, for feeding the inert gas 8, in addition to the vaporizer 4 (see FIG. 6).

In the above-mentioned construction, the equidistantly spaced source gas injectors 107 distribute the source gas 106 uniformly throughout the second space 3. Then, the source gas 106 is supplied through the multiplicity of holes 1a uniformly into the first space 2 and, therefore, uniformly onto the substrate.

Although the MOCVD apparatus is described according to the first to fifth preferred embodiments, the present invention is not limited to the MOCVD apparatus but may be applied to other CVD apparatuses.

While the invention has been described in detail, the foregoing description is in all aspects illustrative and not restrictive. It is understood that numerous other modifications and variations can be devised without departing from the scope of the invention.

What is claimed is:

1. A chemical vapor deposition apparatus for forming a film on a substrate, comprising:
a reactor chamber for receiving said substrate therein;
a partition wall for dividing said reactor chamber into a first space in which said substrate is to be placed, and a second space in which said substrate is not to be placed;
a multiplicity of holes formed in said partition wall; and
a gas feed passage for supplying a source gas into said second space.

2. The chemical vapor deposition apparatus according to claim 1, wherein
said partition wall is formed to cover said substrate from above.

3. The chemical vapor deposition apparatus according to claim 1, further comprising
a heat supply element for applying heat to said second space,
wherein said partition wall is made of quartz.

4. The chemical vapor deposition apparatus according to claim 2, further comprising
a heat supply element for applying heat to said second space,
wherein said partition wall is made of quartz.

5. The chemical vapor deposition apparatus according to claim 1, wherein
said partition wall and a surface of said reactor chamber opposed thereto are of a curved configuration.

6. The chemical vapor deposition apparatus according to claim 2, wherein
said partition wall and a surface of said reactor chamber opposed thereto are of a curved configuration.

7. The chemical vapor deposition apparatus according to claim 3, wherein
said partition wall and a surface of said reactor chamber opposed thereto are of a curved configuration.

8. The chemical vapor deposition apparatus according to claim 4, wherein
said partition wall and a surface of said reactor chamber opposed thereto are of a curved configuration.

9. The chemical vapor disposition apparatus according to claim 2, wherein
said multiplicity of holes include a pair of holes, and
said pair of holes are disposed symmetrically with respect to said substrate as viewed in plan and have respective axes extending in a different direction from a line passing through said pair of holes and the center of said substrate.

10. The chemical vapor disposition apparatus according to claim 4, wherein
said multiplicity of holes include a pair of holes, and
said pair of holes are disposed symmetrically with respect to said substrate as viewed in plan and have respective axes extending in a different direction from a line passing through said pair of holes and the center of said substrate.

11. The chemical vapor disposition apparatus according to claim 6, wherein
said multiplicity of holes include a pair of holes, and
said pair of holes are disposed symmetrically with respect to said substrate as viewed in plan and have respective axes extending in a different direction from a line passing through said pair of holes and the center of said substrate.

12. The chemical vapor disposition apparatus according to claim 8, wherein
said multiplicity of holes include a pair of holes, and
said pair of holes are disposed symmetrically with respect to said substrate as viewed in plan and have respective axes extending in a different direction from a line passing through said pair of holes and the center of said substrate.

13. A chemical vapor deposition apparatus for forming a film on a substrate, comprising:
a reactor chamber for receiving said substrate therein; and
at least two gas feed passages equidistantly spaced circumferentially about said substrate for supplying a source gas into said reactor chamber.

14. The chemical vapor deposition apparatus according to claim 13, further comprising:
a vaporizer for generating said source gas; and
at least two valves formed between said vaporizer and said at least two gas feed passages, respectively, said at least two valves being open alternatively.

15. The chemical vapor deposition apparatus according to claim 14, further comprising
an inert gas feed passage for introducing an inert gas into one of said at least two gas feed passages which is not supplying said source gas.

16. The chemical vapor deposition apparatus according to claim 13, further comprising:
a partition wall for dividing said reactor chamber into a first space in which said substrate is to be placed, and a second space in which said substrate is not to be placed; and
a multiplicity of holes formed in said partition wall,
wherein said at least two gas feed passages supply said source gas into said second space.

17. The chemical vapor deposition apparatus according to claim 14, further comprising:
a partition wall for dividing said reactor chamber into a first space in which said substrate is to be placed, and a second space in which said substrate is not to be placed; and
a multiplicity of holes formed in said partition wall,
wherein said at least two gas feed passages supply said source gas into said second space.

18. The chemical vapor deposition apparatus according to claim 15, further comprising:
a partition wall for dividing said reactor chamber into a first space in which said substrate is to be placed, and a second space in which said substrate is not to be placed; and
a multiplicity of holes formed in said partition wall,
wherein said at least two gas feed passages supply said source gas into said second space.
